(19) United States
(12) Patent Application Publication
(10) Pub. No.: US 2010/0073052 A1
(43) Pub. Date: Mar. 25, 2010

(54) FRACTIONAL RESOLUTION INTEGER-N FREQUENCY SYNTHESIZER

(75) Inventors: Jaehyouk Choi, Atlanta, GA (US); Jongmin Park, San Diego, CA (US); Kyutae Lim, Alpharetta, GA (US); Chang-Ho Lee, Marietta, GA (US); Haksun Kim, Daejeon (KR); Joy Laskar, Marietta, GA (US)

Correspondence Address: SUTHERLAND ASBILL & BRENNAN LLP, 999 PEACHTREE STREET, N.E., ATLANTA, GA, 30309, US

(73) Assignee: Samsung Electro-Mechanics Company, Ltd, Gyunggi-Do (KR)

(21) Appl. No.: 12/563,790

(22) Filed: Sep. 21, 2009

Related U.S. Application Data
(60) Provisional application No. 61/098,508, filed on Sep. 19, 2008.

(51) Int. Cl. H03L 7/08

(52) U.S. Cl. 327/157

(57) ABSTRACT

Embodiments of the invention may provide for a frequency synthesizer capable to generate an output signal in which the frequency is a fractional portion of the reference frequency without a fractional divider. Based on mathematical relationship (“relatively prime”) between the reference frequency and other injection frequencies mixed with the output signal of a voltage controlled oscillator, the synthesizer is able to generate signals evenly spaced in the frequency domain like Fractional-N PLLs. The synthesizer may include an Integer-N PLL, a SSB mixer, frequency dividers, and frequency multipliers. A Integer-N PLL may include a Phase and Frequency Detector, a Charge Pump, a Loop Filter and a Dual Modulus Divider. By not requiring a fractional divider, the frequency synthesizer is able to avoid adopting any compensation circuits such as Sigma-Delta modulator to suppress fractional spurs. Therefore, the chip area, power consumption and complexity will be reduced considerably.

### RELATED APPLICATION

The present application claims priority to U.S. Provisional Application No. 61/098,508, filed on Sep. 19, 2008, and entitled “Fractional Resolution Integer-N Frequency Synthesizer.” The foregoing application is hereby incorporated by reference in its entirety.

### FIELD OF THE INVENTION

The invention relates generally to a wide-bandwidth integer-N Phase Locked Loop (PLL) maintaining high frequency resolution.

### BACKGROUND OF THE INVENTION

A Phase Locked Loop (PLL) is a fundamental part of wireless or wired communication systems. The PLL provides a clock to synchronize operations of components in a system. Depending on its own standard, each application specifies different design parameters, such as a phase noise performance, a maximum spur level, and a settling time. By considering these design parameters, a type and configuration of a PLL is determined. Despites a number of variations, PLLs are categorized into two configurations according to the relation between the frequency of a reference signal and the frequency of a PLL output signal: (i) Integer-N type and (ii) Fractional-N type.

The term Integer-N comes from the fact that the PLL output frequency is any integer multiple of a reference signal frequency. PLLs of this type are simple and straightforward to design, and generally do not require spur suppression techniques. Accordingly, an Integer-N type PLL typically requires a smaller chip area and power consumption as compared to a Fractional-N type PLL. Thus, this conventional Integer-N type PLL type has been used in some communication systems that have less strict specification on generated frequencies. However, Integer-type PLLs have an intrinsic structural limitation. In particular, since the output frequency is fixed as an integer multiple of a reference frequency. Accordingly, if some applications require high frequency resolution, small channel space, the divider number should be very large. This large divider number, N, increases phase noise from a Phase Detector (PD) by 20 log (N), which severely degrades in-band phase noise performance. Furthermore, a low reference frequency will restrict the loop bandwidth because the loop bandwidth cannot exceed one tenth of a reference frequency as a rule of thumb for stability. In this case, phase noise from a voltage controlled oscillator (VCO) cannot be suppressed by a loop filter and an acquisition process becomes slower.

Fractional-N PLLs allow frequency resolution that is a fractional portion of the reference frequency by adopting a component that enables the divider number to change dynamically during the locked state. If the divider number is changed between N and N+1 in the accurate proportion, an average division ratio can be realized that is N plus some arbitrary fraction, K/F. Therefore the reference frequency can be higher than the step size and overall divide number can be reduced. However, fractional-N PLLs have an inherent risk of unwanted fractional spurs at the output. A fractional spur can appear at Fr*K/F and, if F is large, then the system could suffer from close in-band spurs. Thus, an additional solution is typically included to minimize or eliminate these spurs so as not to degrade system performance. Currently, many solutions have been introduced such as a current compensation technique or a delay compensation technique; however, the noise shaping method using Sigma-Delta modulation is regarded as an optimal solution. Although Sigma-Delta PLLs have shown good performance, a high-order Sigma-Delta modulator for a required noise-shaping takes large power consumption and considerable chip area.

As shown above, while Fractional-N PLLs have tackled an intrinsic limitation of Integer-N PLLs, there is a trade off among a frequency resolution, a loop bandwidth relating with a acquisition speed, and a phase noise performance. However, additional techniques to suppress fractional spurs make PLLs large, costly and complicated.

### SUMMARY OF THE INVENTION

In order to generate an output signal frequency of a fractional portion of the reference frequency without a fractional-N divider, an Integer-N PLL loop in accordance with an example embodiment of the invention may adopt a single side band (SSB) mixer to mix a voltage controlled oscillator (VCO) output signal with a signal whose frequency is mathematically calculated. Since each of these mixed signals and the reference signal frequency have a relationship of relatively prime, as described herein, the PLL can synthesize all the frequencies which are evenly spaced in the frequency domain like Fractional-N PLLs do. Since the added signal will be directly generated from a same crystal oscillator using frequency dividers and multipliers, the PLL operates as a single-loop system, according to an example embodiment of the invention. Thus, the example system in accordance with an example embodiment of the invention may maintain simple and straightforward characteristics similar to those of a single-loop Integer-N PLL.

According to an example embodiment of the invention, there is a system for a phase locked loop. The system may include a first frequency divider that divides an input frequency to generate a reference frequency; a phase and frequency detector that receives the reference frequency and a feedback signal to provide a control signal; a charge pump that receives the control signal and generates a voltage signal; a voltage controlled oscillator that receives the voltage signal and generates an output frequency; and a mixer that mixes the output frequency with an injection frequency to generate a mixed signal, where the mixed signal is utilized to generate the feedback signal received by the phase and frequency detector, where the reference frequency is relatively prime with respect to the injection frequency.

According to another example embodiment of the invention, there is a method for providing a phase locked loop. The method may include dividing in input frequency by a first frequency divider to generate a reference frequency; generating a control signal by a phase and frequency detector based upon a comparison of the reference frequency and a feedback signal; generating a voltage signal by a charge pump in response to the control signal; generating an output signal by a voltage controlled oscillator based upon the voltage signal; and mixing the output signal with an injection frequency by a mixer to generate a mixed signal, where the mixed signal is utilized to generate the feedback signal received by the phase and frequency detector, where the reference frequency is relatively prime with respect to the injection frequency.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 illustrates the block diagram of a Fractional Resolution Integer-N PLL in accordance with an example embodiment of the invention.

FIG. 2 illustrates a spur suppression effect of Fractional Resolution Integer-N PLL in accordance with an example embodiment of the invention.

### DETAILED DESCRIPTION OF THE INVENTION

The invention now will be described more fully hereinafter with reference to the accompanying drawings, in which some, but not all embodiments of the invention are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

Embodiments of the invention may provide a frequency synthesizer that is operative to generate signals with fractional integer frequencies using an Integer-N type PLL and an SSB mixer. Using the relationship between a frequency of the reference signal and signals multiplied by an SSB mixer, the frequency synthesizer can generate any signal with a specified fractional frequency resolution without a fractional divider that is required for conventional Factional-N PLLs.

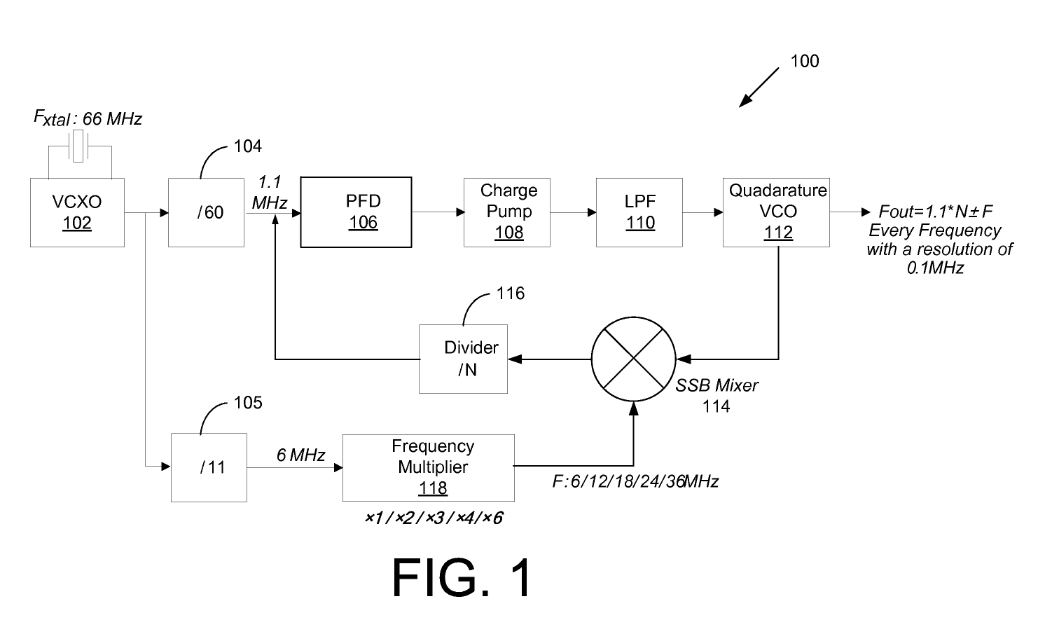

FIG. 1 illustrates a block diagram of an example frequency synthesizer 100, according to an example embodiment of the invention. As shown in FIG. 1, the frequency synthesizer 100 may include on or more of the following components: a voltage controlled crystal oscillator (VCXO) 102, a first frequency divider 104 (e.g., divides by 60), a second frequency divider 105 (e.g., divides by 11), a phase and frequency detector (PFD) 106, a charge pump 108, a filter 110 (e.g., loop filter (LPF)), a voltage controlled oscillator 112 (e.g., a quadrature VCO), a single side band (SSB) mixer 114, a third divider 116 (e.g., a divide-by-N divider), and a frequency multiplier 118. It will be appreciated that the third divider 116 may be a dual modulus divider, according to an example embodiment of the invention. In an example embodiment of the invention, the first frequency divider 104, the PFD 106, the charge pump 108, the filter 110, the voltage controlled oscillator 112, and the third divider 116 may configured as an Integer-N type PLL having an SSB mixer 114 to provide injected frequencies, as shown in FIG. 1.

During operation, the voltage controlled crystal oscillator 102 generates a crystal frequency Fₓₜₐ, which may be provided to the first frequency divider 104 that may perform frequency division according to a first integer value (e.g., /60). The output of the divider 104 may be provided as a reference frequency to the phase and frequency detector 106. The phase and frequency detector 106 may also receive a feedback signal from the feedback loop that comprises the third divider 116. The phase and frequency detector 106 may compare the reference frequency to the feedback signal to generate a pump control signal (e.g., voltage pulses) that are provided to the charge pump 108. In particular, the pump control signal (e.g., voltage pulse (e.g., Up/Down)) may direct the charge pump 108 to supply charge amounts in proportion to a difference between the reference frequency and the feedback signal. A voltage signal output by the charge pump 108 may be filtered by a filter 110 (e.g., a loop filter) prior to receipt by a voltage controlled oscillator 112, which may be a quadrature voltage controlled oscillator, according to an example embodiment of the invention. The output of the voltage controlled oscillator may provide an output frequency Fout, as described herein, according to an example embodiment of the invention.

As also shown in FIG. 1, the crystal frequency Fₓₜₐₗ may also be provided to the second frequency divider 105 that may perform frequency division according to a second integer value (e.g., /11). The output of the second divider 105 may be provided as a base frequency to a frequency multiplier 118. The frequency divider 118 may be operative to multiply the based frequency by one a predetermined number of multipliers. The output of the frequency multiplier 118, which may be the injected frequency F, may be provided to the single side band mixer 114. The single side band mixer 114 may be operative to mix the output received from the voltage controlled oscillator 112 with any injected frequency from the frequency multiplier 118. The mixed signal generated by the single side band mixer 114 may be provided to the third divider 116 having a divisor of N, which as described above, provides an output that is the feedback signal received by the phase and frequency detector 106.

In the example embodiment of FIG. 1, the reference frequency output by the first divider 104 is configured to be a fractional number of any integer number, and is relatively prime to the other numbers used as injected signal frequencies from the frequency multiplier 118. Generally, relatively prime (or coprime) refers to the situation where the greatest common whole number divisor is 1. As an example, FIG. 1 shows an example in which 1.1 MHz (or 11*10̂5 Hz) is used as a reference frequency and 6, 12, 18, 24 and 36 MHz (or 60-, 120-, 180-, 240-, and 360- *10̂5 Hz) as injected frequencies, which are all relatively prime in relation to 11. In an example embodiment of the invention, to achieve the frequency resolution of 0.1 MHZ in the PLL, all 5 of the injected frequencies 6/12/18/24/36 (MHz) may be relatively prime to 11 (MHz). If these 5 injected frequencies are relatively prime to 11, then by adding or subtracting one of 5 injected frequencies to or from the VCO output frequencies, 1.1 MHz*[10N2+N1], in Table I below, all the PLL output frequencies with the frequency resolution of 0.1 MHz can be synthesized. This property is based on the fact that if 5 different injected frequencies are relatively prime to 11, we can obtain 10 unique remainders, as illustrated in Table II. Accordingly, in this situation, the output Fout from the voltage controlled oscillator 112 may be equal to 1.1 MHz*N±F, where N is determined by the third divider 116 and F is the injected frequency provided by the output of the frequency multiplier 118. Through the use of proper simple dividers and multipliers, these injected signals can be easily generated from the crystal oscillator.

It will be appreciated that the example values for the dividers, multipliers, and frequencies illustrated in FIG. 1 are for purposes of illustration only, and that other values may be utilized without departing from example embodiments of the invention. By way of example, the VCXO 102 may operate at a frequency other than 66 MHz, and the frequency dividers 104, 105 are not required to be /60 and /11 dividers, respectively. Indeed, the mathematical relationship of relatively prime may be used to determine the divisors for dividers 104, 105 in accordance with example embodiments of the invention

A verification that the an example frequency synthesizer comprising a simple Integer-N type PLL with a SSB mixer is operative to generate signals with a fractional frequency resolution will now be discussed in further detail. In particular, the output frequency Fout can be determined as follows in Table I. Thus, a frequency synthesizer with a fractional frequency resolution can be easily implemented without a fractional divider which introduces large in-band fractional spurs, according to an example embodiment of the invention.

TABLE I
Fout = 1.1 MHz * N ± F, where N equals 10N2 + N1, where N1 is any
integer between 0 to 9, and where F is the set of injected frequencies;
= 1.1 MHz * [10N2 + N1] ± F, where the injected frequencies F can be
any set of unique numbers that are relatively prime with respect to 11 and
have different residues/remainders when divided by 11;
= 1.1 MHz * [10N2 + N1] ± [6, 12, 18, 24, 36]MHz, where the set of
injected frequencies F is selected in this example to be the set of [6, 12,
18, 24, 36] MHz, all of which are relatively prime with respect to 11 and
have different residues/remainders when divided by 11;
= 11 MHz * N2 + 0.1 MHz * N1 ± [6, 12, 18, 24, 36]MHz, which is
simplified below in Table II;
= 11 MHz + [N2 ± k] + [0, 1, 2, 3, 4, 5, 6, 7, 8, 9, 10] + 0.1 MHz * N1,
where k in this example is are the integers between 0 and 4, as shown in
Table II;
= A MHz + 0.1 MHz * N1, where A is any positive integer, and N1 is any
integer between 0 and 9. This implies that the output frequency Fout can
be any frequency with a 0.1 MHz resolution.

TABLE II

11 * N2 + 12 = 11 * [N2 + 1] + 1
11 * N2 + 24 = 11 * [N2 + 2] + 2
11 * N2 + 36 = 11 * [N2 + 3] + 3
11 * N2 − 18 = 11 * [N2 − 1] + 4
11 * N2 − 6 = 11 * [N2 − 1] + 5
11 * N2 + 6 = 11 * [N2 + 0] + 6
11 * N2 + 18 = 11 * [N2 + 1] + 7
11 * N2 − 36 = 11 * [N2 − 4] + 8
11 * N2 − 24 = 11 * [N2 − 3] + 9
11 * N2 − 12 = 11 * [N2 − 2] + 10

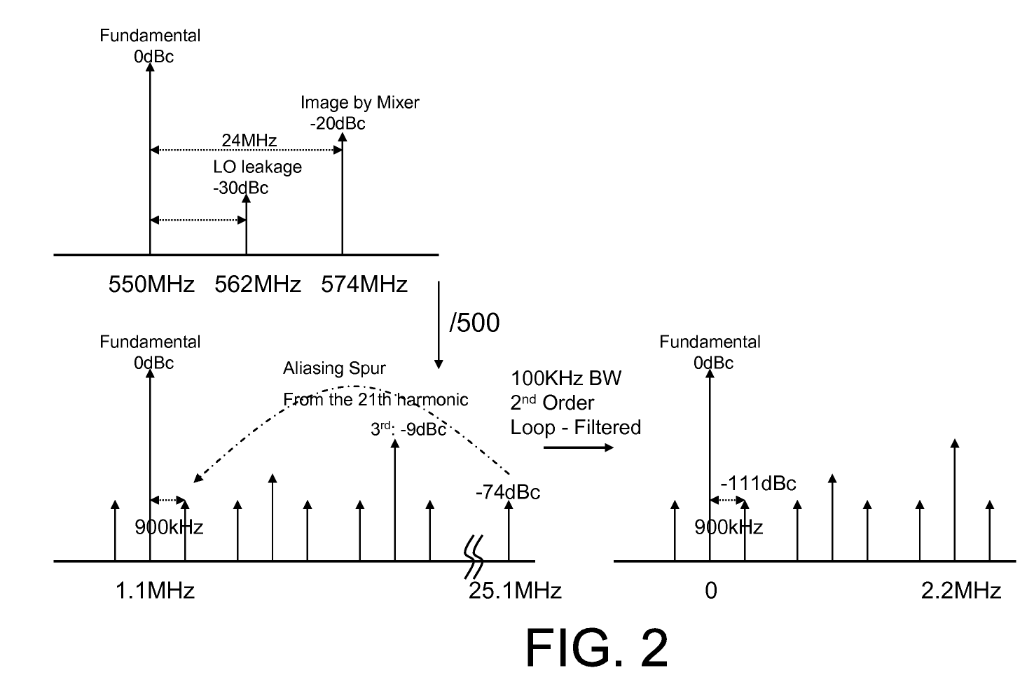

FIG. 2 illustrates the spur suppression effect of an example embodiment of the invention. As shown in FIG. 2, spurs from the image signal (e.g., at 574 MHz) and the LO leakage from a mixer (e.g., at 562 MHz) are suppressed by 20 log N and far from the fundamental signal (e.g., at 550 MHz) after a divider. On the other hand, aliasing signals introduced while passing through a divider should be considered since that could get into the close-band. However, this aliasing spur is greatly suppressed by a divider as well. Therefore, even with a typical a SSB mixer, an example embodiment of the invention shows better spur performance compared to conventional Fractional-N PLLs. By not utilizing a fractional divider, a frequency synthesizer in accordance with an example embodiment of the invention is able to avoid adopting any compensation circuits such as Sigma-Delta modulator to suppress fractional spurs. Therefore, the chip area and power consumption will be reduced considerably.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A system for a phase locked loop, comprising:
a first frequency divider that divides an input frequency to generate a reference frequency;
a phase and frequency detector that receives the reference frequency and a feedback signal to provide a control signal;
a charge pump that receives the control signal and generates a voltage signal;
a voltage controlled oscillator that receives the voltage signal and generates an output frequency; and
a mixer that mixes the output frequency with an injection frequency to generate a mixed signal, wherein the mixed signal is utilized to generate the feedback signal received by the phase and frequency detector,
wherein the reference frequency is relatively prime with respect to the injection frequency.

2. The system of claim 1, wherein the reference frequency is relatively prime with respect to the injection frequency because the greatest common whole number divisor is 1.

3. The system of claim 1, further comprising:
a voltage controlled crystal oscillator that generates the input frequency.

4. The system of claim 1, further comprising:
a second frequency divider that divides the mixed signal to generate the feedback signal received by the phase and frequency detector.

5. The system of claim 1, further comprising:
a second frequency divider that divides the input frequency to generate a base frequency;
a frequency multiplier that multiplies the base frequency by a multiplication factor to generate the injection frequency.

6. The system of claim 5, wherein the frequency multiplier is operative to multiply the base frequency by one of a plurality of multiplication factors to generate one of a plurality of injection frequencies, wherein each of the injection frequencies is relatively prime with respect to the reference frequency.

7. The system of claim 5, wherein the second frequency divider is a divide-by-11 frequency divider.

8. The system of claim 1, wherein the voltage signal generated by the charge pump is filtered prior to being received by the voltage controlled oscillator.

9. The system of claim 1, wherein the voltage signal is filtered by a loop filter.

10. The system of claim 1, wherein the voltage controlled oscillator is a quadrature voltage controlled oscillator, and wherein the mixer is a single side band mixer.

11. A method for providing a phase locked loop, comprising:
dividing in input frequency by a first frequency divider to generate a reference frequency;
generating a control signal by a phase and frequency detector based upon a comparison of the reference frequency and a feedback signal;
generating a voltage signal by a charge pump in response to the control signal;
generating an output signal by a voltage controlled oscillator based upon the voltage signal; and
mixing the output signal with an injection frequency by a mixer to generate a mixed signal, wherein the mixed signal is utilized to generate the feedback signal received by the phase and frequency detector,
wherein the reference frequency is relatively prime with respect to the injection frequency.

12. The method of claim 11, wherein the reference frequency is relatively prime with respect to the injection frequency because the greatest common whole number divisor is 1.

13. The method of claim 11, further comprising:
generating the input frequency using a voltage controlled crystal oscillator.

14. The method of claim 11, further comprising:
dividing the mixed signal by a second frequency divider to generate the feedback signal received by the phase and frequency detector.

15. The method of claim 11, further comprising:
dividing the input frequency by a second frequency divider to generate a base frequency; and
multiplying, by a frequency multiplier, the base frequency by a multiplication factor to generate the injection frequency.

16. The method of claim 15, wherein the frequency multiplier is operative to multiply the base frequency by one of a plurality of multiplication factors to generate one of a plurality of injection frequencies, wherein each of the injection frequencies is relatively prime with respect to the reference frequency.

17. The method of claim 15, wherein the second frequency divider is a divide-by-11 frequency divider.

18. The method of claim 11, further comprising:
filtering the voltage signal generated by the charge pump prior to receipt by the voltage controlled oscillator.

19. The method of claim 11, wherein the voltage signal is filtered by a loop filter.

20. The method of claim 11, wherein the voltage controlled oscillator is a quadrature voltage controlled oscillator, and wherein the mixer is a single side band mixer.
